(19) United States
(12) Patent Application Publication
(10) Pub. No.: US 2019/0386048 A1
(43) Pub. Date: Dec. 19, 2019

(54) SEMICONDUCTOR DEVICE AND METHOD FOR FORMING THE SAME

(71) Applicant: Vanguard International Semiconductor Corporation, Hsinchu (TW)

(72) Inventors: Hsin-Hui LEE, Kaohsiung City (TW); Han-Liang TSENG, Hsinchu City (TW); Hsueh-Jung LIN, Jhubei City (TW)

(73) Assignee: Vanguard International Semiconductor Corporation, Hsinchu (TW)

(21) Appl. No.: 16/007,264

(22) Filed: Jun. 13, 2018

(51) Int. Cl. H01L 27/146; H01L 31/167; H01L 31/0216

(52) U.S. Cl. CPC H01L 27/14623; H01L 27/14685; H01L 27/14643; G06K 9/00013; H01L 31/167; H01L 31/02164; H01L 27/14636

(57) ABSTRACT

A method for forming a semiconductor device is provided. The method includes providing a substrate, forming a first light-shielding layer on the substrate, and performing a first lithography process to pattern the first light-shielding layer to form a plurality of first openings in the first light-shielding layer. The first openings expose pixels of the substrate. The method also includes placing a first stencil on the first light-shielding layer. The first stencil has a first openwork pattern which exposes the pixels of the substrate. The method also includes providing a first material. The first material includes a transparent material. The method also includes applying the first material onto the substrate through the first stencil to cover the pixels and fill the first openings, such that a plurality of first transparent pillars made of the first material are formed on the pixels.

### BACKGROUND

Embodiments of the present disclosure relate to a method for forming a semiconductor device, and in particular they relate to a method for forming a semiconductor device which includes a transparent material and a light-shielding material.

Semiconductor devices are used in a variety of electronic applications. For example, semiconductor devices may be used to serve as a fingerprint identification device (or at least a portion of a fingerprint identification device). The fingerprint identification device may be made of many optical elements. For example, the optical elements may include a light collimator, a beam splitter, a focusing mirror, and a linear sensor.

The function of the light collimator is to collimate the light, so as to reduce the energy loss resulting from the scattering of the light. For example, the light collimator may be used in a fingerprint identification device to increase the performance of the fingerprint identification device.

However, existing light collimators and the formation methods thereof are have not been satisfactory in every respect.

### SUMMARY

Some embodiments of the present disclosure relate to a method for forming a semiconductor device. The method includes providing a substrate, forming a first light-shielding layer on the substrate, and performing a first lithography process to pattern the first light-shielding layer to form a plurality of first openings in the first light-shielding layer. The first openings expose a plurality of pixels of the substrate. The method also includes placing a first stencil on the first light-shielding layer. The first stencil has a first openwork pattern which exposes the pixels of the substrate. The method also includes providing a first material. The first material includes a transparent material. The method also includes applying the first material onto the substrate through the first stencil to cover the pixels and fill the first openings, so that a plurality of first transparent pillars made of the first material are formed on the pixels.

Some embodiments of the present disclosure relate to a semiconductor device. The semiconductor device includes a substrate. The substrate includes a plurality of pixels. The semiconductor device also includes a light collimator layer disposed on the substrate. The light collimator layer includes a first light-shielding layer disposed on the substrate, a plurality of first transparent pillars disposed on the substrate, a second light-shielding layer disposed on the first light-shielding layer, and a plurality of second transparent pillars disposed on the first transparent pillars and covering the first transparent pillars. The first transparent pillars cover the pixels of the substrate.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIGS. 1A, 1B, 1C, 1D, 1E, 1F, and 1G are a series of cross-sectional views illustrating a method for forming a semiconductor device according to some embodiments of the present disclosure.

FIG. 1D′ illustrates a top view of the stencil 104 according to some embodiments of the present disclosure.

FIG. 1G′ illustrates a cross-sectional view of the semiconductor device 10 according to some embodiments of the present disclosure.

FIG. 1G″ illustrates a cross-sectional view of the semiconductor device 10′ according to some embodiments of the present disclosure.

FIGS. 2A, 2B, 2C, 2D, 2E, 2F, and 2G are a series of cross-sectional views illustrating a method for forming a semiconductor device according to some embodiments of the present disclosure.

FIG. 2D′ illustrates a top view of the stencil 204 according to some embodiments of the present disclosure.

FIG. 2G′ illustrates a cross-sectional view of the semiconductor device 20 according to some embodiments of the present disclosure.

FIG. 2G″ illustrates a cross-sectional view of the semiconductor device 20′ according to some embodiments of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various embodiments. This repetition is for the purpose of simplicity and clarity and does not in itself dictate a relationship between the various embodiments and/or configurations discussed.

It should be understood that additional steps can be implemented before, during, or after the illustrated methods, and some steps might be replaced or omitted in other embodiments of the illustrated methods.

Unless otherwise defined, all terms (including technical and scientific terms) used herein have the same meanings as commonly understood by one of ordinary skill in the art to which the present disclosure pertains. It should be understood that these terms, such as those defined in commonly used dictionaries, should be interpreted as having meanings consistent with the relevant art and the background or context of the present disclosure, and should not be interpreted in an idealized or overly formal manner, unless specifically defined in the embodiments of the present disclosure.

### Embodiment 1

In the method for forming the semiconductor device of the present embodiment, a light-shielding layer is formed on a substrate and a plurality of openings are formed in the light-shielding layer, and then a stencil printing process is used to dispose a transparent material on the substrate to form a plurality of transparent pillars. The light-shielding layer and the transparent pillars may serve as the light collimator layer of the semiconductor device (e.g., a fingerprint identification device). Since the cost of the stencil printing process is low, the manufacturing cost of the light collimator layer and the semiconductor device including the light collimator layer may be reduced.

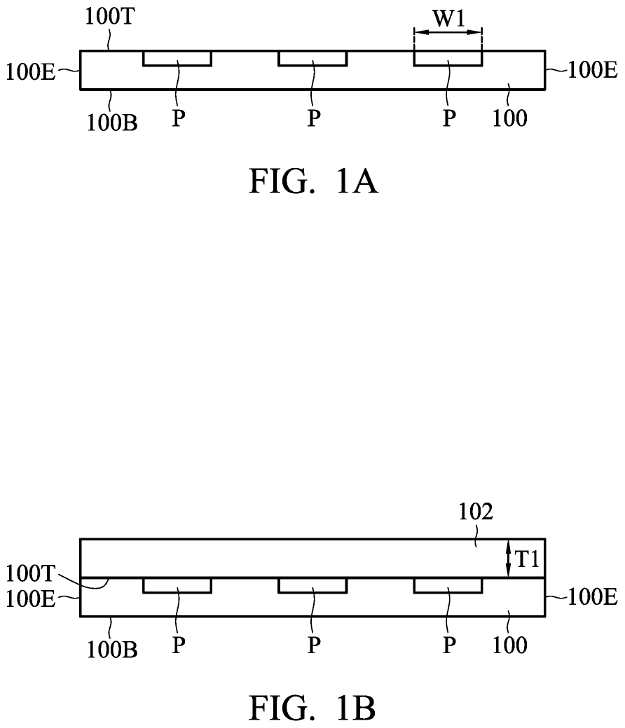

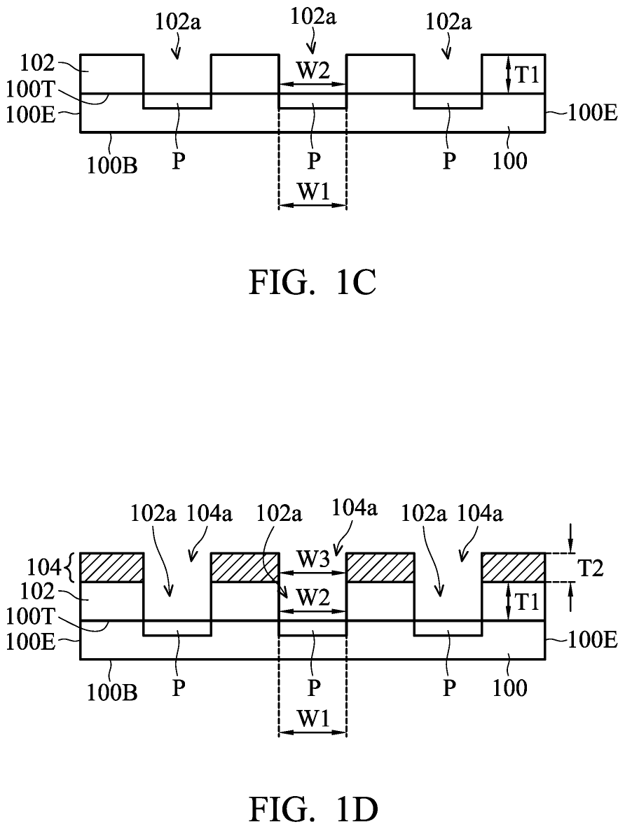

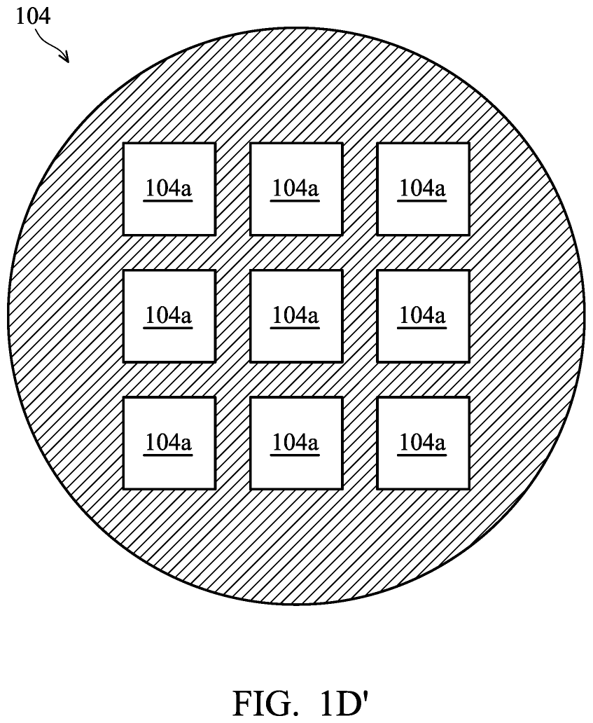

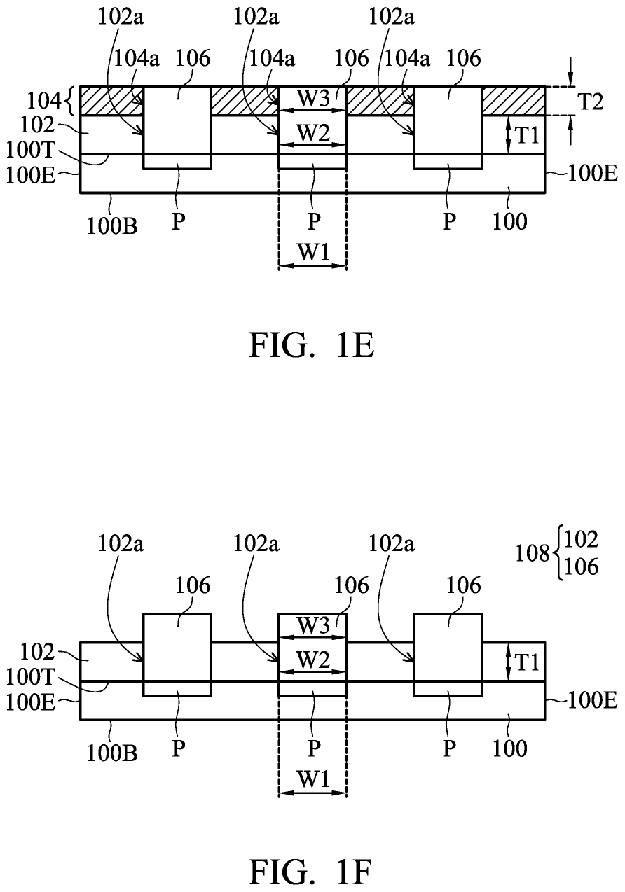

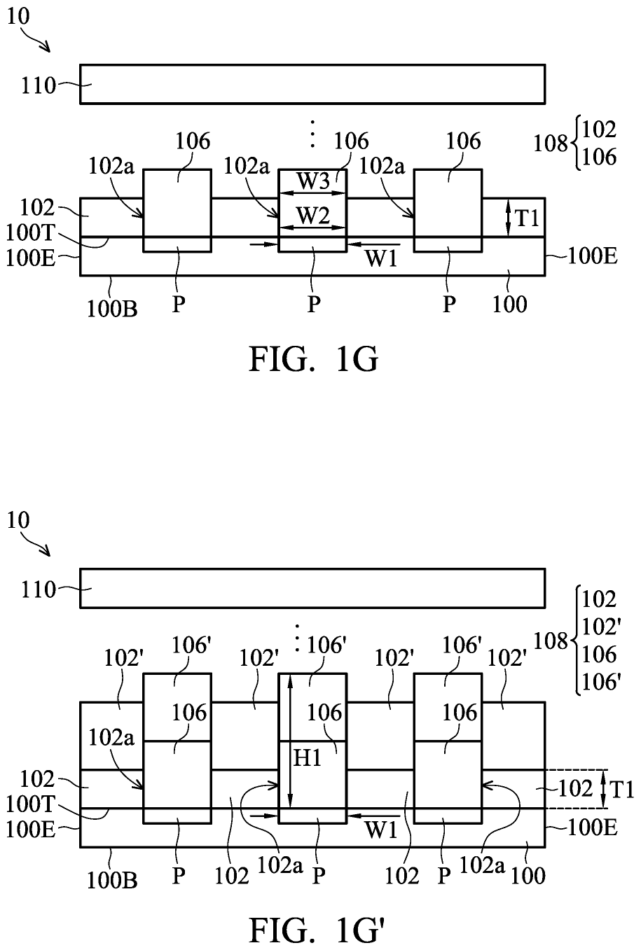

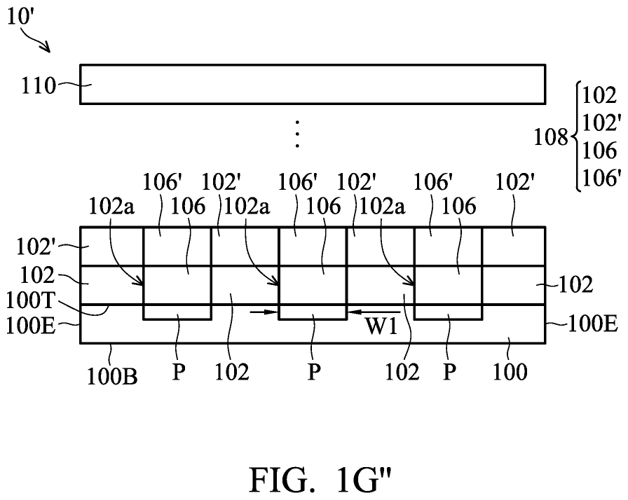

FIG. 1A illustrates the initial step of the method for forming the semiconductor device of the present embodiment. As shown in FIG. 1A, a substrate 100 is provided. The substrate 100 may have a top surface 100T and a bottom surface 100B opposite to the top surface 100T, and a side (or edge) 100E of the substrate 100 is between the top surface 100T and the bottom surface 100B.

In some embodiments, the substrate 100 may be made of an elementary semiconductor (e.g., silicon or germanium), a compound semiconductor (e.g., silicon carbide (SiC), gallium arsenic (GaAs), indium arsenide (InAs), or indium phosphide (InP)), an alloy semiconductor (e.g., silicon germanium (SiGe), silicon germanium carbide (SiGeC), gallium arsenic phosphide (GaAsP), or gallium indium phosphide (GaInP)), any other applicable semiconductor, or a combination thereof. In some embodiments, the substrate 100 may be a semiconductor-on-insulator (SOI) substrate. The semiconductor-on-insulator substrate may include a bottom substrate, a buried oxide layer disposed on the bottom substrate, and a semiconductor layer disposed on the buried oxide layer. In some embodiments, the substrate 100 may be a semiconductor wafer (e.g., a silicon wafer, or any other applicable semiconductor wafer).

In some embodiments, the substrate 100 may include various p-type doped regions and/or n-type doped regions formed by a process such as an ion implantation process and/or a diffusion process. For example, the doped regions may be configured to form a transistor, a photodiode, and/or a light-emitting diode, but the present disclosure is not limited thereto.

In some embodiments, the substrate 100 may include various isolation features to separate various device regions in the substrate 100. For example, the isolation features may include a shallow trench isolation (STI) feature, but the present disclosure is not limited thereto. The formation of a STI feature may include etching a trench in the substrate 100 and filling in the trench with insulator materials (e.g., silicon oxide, silicon nitride, or silicon oxynitride). The filled trench may have a multi-layer structure such as a thermal oxide liner layer with silicon nitride filling the trench. A chemical mechanical polishing (CMP) process may be performed to polish back excessive insulator materials and planarize the top surface of the isolation features.

In some embodiments, the substrate 100 may include various conductive features (e.g., lines or vias). For example, the conductive features may be made of aluminum (Al), copper (Cu), tungsten (W), an alloy thereof, any other applicable conductive material, or a combination thereof.

Still referring to FIG. 1A, in some embodiments, the substrate 100 may include a plurality of pixels P. In some embodiments, the pixels P receive the light signals and convert the light signals into electric current signals. In some embodiments, the pixels P of the substrate 100 may be arranged in an array, but the present disclosure is not limited thereto. For example, in some embodiments, each of the pixels P of the substrate 100 may include or correspond to at least one photodiode and/or other applicable elements, but the present disclosure is not limited thereto. As shown in FIG. 1A, each of the pixels P may have a width W1. The width W1 may be between 2 μm and 200 μm, but the present disclosure is not limited thereto.

Then, as shown in FIG. 1B, a light-shielding layer 102 is formed on the top surface 100T of the substrate 100. The light-shielding layer 102 may be made of a light-shielding material. For example, the light-shielding material may include photoresist (e.g., black photoresist, or other applicable photoresist which is not transparent), ink (e.g., black ink, or other applicable ink which is not transparent), molding compound (e.g., black molding compound, or other applicable molding compound which is not transparent), solder mask (e.g., black solder mask, or other applicable solder mask which is not transparent), black-epoxy polymer, any other applicable material, or a combination thereof. In some embodiments, the light-shielding layer 102 may include a light curing material, a thermal curing material, or a combination thereof.

As shown in FIG. 1B, the light-shielding layer 102 may have a thickness T1. For example, the thickness T1 may be between 2 μm and 150 μm (e.g., within a range of 5 μm to 100 μm), but the present disclosure is not limited thereto.

Then, as shown in FIG. 1C, the light-shielding layer 102 is patterned to form a plurality of openings 102a in the light-shielding layer 102. In some embodiments, the openings 102a correspond to the pixels P. In other words, in these embodiments, each of the openings 102a may expose at least a portion of the corresponding pixel P thereof. As shown in FIG. 1C, each of the openings 102a may have a thickness W2. For example, the thickness W2 may be between 2 μm and 200 μm, but the present disclosure is not limited thereto.

In some embodiments, as shown in FIG. 1C, the width W2 of the opening 102a may be substantially equal to the width W1 of the pixel P. In other words, in these embodiments, sidewalls of the opening 102a may be aligned with sidewalls of the corresponding pixel P. In some other embodiments, the width W2 of the opening 102a is greater than the width W1 of the pixel P.

In some embodiments, the pixels P of the substrate 100 are arranged in an array, and thus the openings 102a corresponding to the pixels P are also arranged in an array. The openings 102a may be configured to have any applicable shape according to design requirements. For example, in some embodiments, in a top view, the openings 102a may be rectangular, round, oval, oblong, hexagonal, irregular-shaped, any other applicable shape, or a combination thereof.

In some embodiments, the patterning process for forming the openings 102a may include a lithography process. For example, the lithography process may include mask aligning, exposure, post-exposure baking, developing photoresist, any other applicable process, or a combination thereof.

Then, as shown in FIG. 1D, a stencil 104 is placed on the top surface 100T of the substrate 100 and the light-shielding layer 102. In some embodiments, the stencil 104 may have a plurality of openings 104a corresponding to the pixels P of the substrate 100. In other words, in theses embodiments, after the stencil 104 is placed on the top surface 100T of the substrate 100 and the light-shielding layer 102, each of the openings 104a may expose at least a portion of the corresponding pixel P thereof. In some embodiments, as shown in FIG. 1D, after the stencil 104 is placed on the top surface 100T of the substrate 100 and the light-shielding layer 102, the openings 104a are connected to the openings 102a.

As shown in FIG. 1D, the stencil 104 may have a thickness T2, and each of the openings 104a may have a width W3. For example, the thickness T2 may be between 20 μm and 200 μm, but the present disclosure is not limited thereto. For example, the width W3 may be within a range of 2 μm to 200 μm, but the present disclosure is not limited thereto.

In some embodiments, as shown in FIG. 1D, the width W3 of the opening 104a may be substantially equal to the width W1 of the pixel P. In other words, in these embodiments, sidewalls of the opening 104a may be aligned with sidewalls of the corresponding pixel P. In some other embodiments, the width W3 of the opening 104a is greater than the width W1 of the pixel P. In some embodiments, as shown in FIG. 1D, the width W3 of the opening 104a may be substantially equal to the width W2 of the opening 102a. In other words, in these embodiments, sidewalls of the opening 104a may be aligned with sidewalls of the corresponding opening 102a. In some other embodiments, the width W3 of the opening 104a is greater than the width W2 of the opening 102a.

Then, referring to FIG. 1D′ which illustrates a top view of the stencil 104, in some embodiments shown in FIG. 1D′, the openings 104a of the stencil 104 form an openwork pattern in the stencil 104. In subsequent steps, a material (e.g., a transparent material) may be disposed on the top surface 100T of the substrate 100 through the openwork pattern of the stencil 104, such that the material on the top surface 100T of the substrate 100 may have a pattern corresponding to the openwork pattern of the stencil 104. The details will be discussed in the following paragraphs.

In some embodiments, the pixels P of the substrate 100 are arranged in an array, and thus the openings 104a corresponding to the pixels P are also arranged in an array. It should be understood that although the openings 104a of the embodiments illustrated in FIG. 1D′ are arranged in a 3×3 array, the present disclosure is not limited thereto. In some other embodiments, the openings 104a may be arranged in an array having any other applicable number of columns and any other applicable number of rows according to design requirements.

In some embodiments, as shown in FIG. 1D′, the openings 104a may be substantially rectangular, but the present disclosure is not limited thereto. In some other embodiments, the openings 104a may be round, oval, oblong, hexagonal, irregular-shaped, any other applicable shape, or a combination thereof according to design requirements.

For example, the stencil 104 may be made of steel, but the present disclosure is not limited thereto. For example, the openings 104a may be formed in the stencil 104 by a mechanical drilling process, but the present disclosure is not limited thereto.

Then, as shown in FIG. 1E, a plurality of transparent pillars 106 are formed on the substrate 100. In some embodiments, as shown in FIG. 1E, the transparent pillars 106 are disposed in the openings 102a and the openings 104a, and the transparent pillars 106 cover the pixels P of the substrate 100. The transparent pillars 106 may be made of a first material. In some embodiments, the first material may include a transparent material (e.g., transparent photoresist, polyimide, any other applicable material, or a combination thereof). In some embodiments, the first material may include a light curing material, a thermal curing material, or a combination thereof. In some embodiments, the flowability of the first material may be the same as or similar to gel or glue.

In some embodiments, the stencil 104 may be used to perform a stencil printing process to coat (or print) the first material onto the top surface 100T of the substrate 100. In some embodiments, in the stencil printing process, the first material is disposed on the stencil 104, and then a squeegee or a roller (not shown in the figures) may be moved on the top surface of the stencil 104 along a direction parallel to the top surface 100T of the substrate 100. The squeegee or the roller may provide an applicable pressure on the first material, such that the first material is squeezed into the openings 104a and the openings 102a from the top surface of the stencil 104. In some embodiments, since the first material is disposed on the top surface 100T of the substrate 100 through the openwork pattern of the stencil 104, the pattern of the transparent pillars 106 made of the first material may correspond to the openwork pattern of the stencil 104. In some embodiments, the pattern of the transparent pillars 106 may be substantially the same as the openwork pattern of the stencil 104.

In some embodiments, since the light-shielding layer 102 and the openings 102a exposing the pixels P are formed before the first material is coated (or printed) on the top surface 100T of the substrate 100 by performing the stencil printing process with the stencil 104, the transparent pillars 106 made of the first material may be precisely disposed on the pixels P. Therefore, the collimating function of the light collimator layer (i.e., the light collimator layer 108 which will be discussed in the following paragraphs) may be improved.

Then, as shown in FIG. 1F, the stencil 104 is removed from the substrate 100 and the light-shielding layer 102. In some embodiments, a curing process may be performed to cure the first material of the transparent pillars 106 after the stencil 104 is removed from the substrate 100 and the light-shielding layer 102. For example, the curing process may be a light curing process, a thermal curing process, or a combination thereof.

In some embodiments, as shown in FIG. 1F, the transparent pillars 106 and the light-shielding layer 102 may serve as a light collimator layer 108 of a semiconductor device. In some embodiments, the light-shielding layer 102 and the transparent pillars 106 of the light collimator layer 108 may be staggered with each other.

In some embodiments, the light-shielding layer 102 of the light collimator layer 108 is black (e.g., the light-shielding layer 102 is made of black photoresist, black ink, black molding compound, or black solder mask), and thus the collimating function of the light collimator layer 108 may be improved.

For example, in some embodiments, a light source (e.g., a light-emitting diode) (not shown in the figures), a blocking layer (not shown in the figures), any other applicable element, or a combination thereof may be disposed on the light collimator layer 108, and a cover plate 110 (e.g., a glass cover plate) may be disposed on these optical elements to form a semiconductor device 10 (as shown in FIG. 1G) such as a fingerprint identification device.

In some embodiments, the steps illustrated in FIGS. 1B to 1F may be repeated (e.g., repeated for twice, three times, or any other applicable number of times), such that the light collimator layer 108 of the semiconductor device 10 may include more light-shielding layers and transparent pillars, further improving the collimating function of the light collimator layer 108. For example, as shown in FIG. 1G′, in some embodiments, the steps illustrated in FIGS. 1B to 1F may be repeated to form a light-shielding layer 102′ the same as or similar to the light-shielding layer 102 on the light-shielding layer 102, and to form transparent pillars 106′ the same as or similar to the transparent pillars 106 on the transparent pillars 106. In some embodiments, the steps illustrated in FIGS. 1B to 1F may be repeated for any applicable number of times to increase the ratio of the sum of the heights of the transparent pillars on a pixel P to the width of the pixel P (e.g., H1/W1), so as to improve the collimating function of the light collimator layer 108. In some embodiments, the ratio of the sum of the heights of the transparent pillars on a pixel P to the width of the pixel P (e.g., H1/W1) may be between 2 and 30 (e.g., within a range of 10 to 30).

In some embodiments, as shown in FIG. 1G′, the top surfaces of the transparent pillars 106 are higher than the top surface of the light-shielding layer 102. In some embodiments, as shown in FIG. 1G′, the top surfaces of the transparent pillars 106′ are higher than the top surface of the light-shielding layer 102′.

In some embodiments, the light-shielding layer 102′ may be in direct contact with the light-shielding layer 102. In some embodiments, the light-shielding layer 102 and the light-shielding layer 102′ may be made of the same material, but the present disclosure is not limited thereto. In some other embodiments, the light-shielding layer 102 and the light-shielding layer 102′ may be made of different materials.

In some embodiments, the transparent pillars 106′ may be in direct contact with the transparent pillars 106. In some embodiments, the transparent pillars 106 and the transparent pillars 106′ may be made of the same material, but the present disclosure is not limited thereto. In some other embodiments, the transparent pillars 106 and the transparent pillars 106′ may be made of different materials.

In summary, in the method for forming the semiconductor device of the present embodiment, a light-shielding layer is formed on a substrate and a plurality of openings are formed in the light-shielding layer, and then a transparent material is disposed on the substrate to form a plurality of transparent pillars by a stencil printing process. The light-shielding layer and the transparent pillars may serve as the light collimator layer of the semiconductor device (e.g., a fingerprint identification device). Since the cost of the stencil printing process is low, the manufacturing cost of the light collimator layer and the semiconductor device including the light collimator layer may be reduced. In addition, in some embodiments, since the light-shielding layer and the openings which are in the light-shielding layer and expose the pixels of the substrate are formed before the transparent pillars are formed, the transparent pillars may be precisely disposed on the pixels of the substrate. Therefore, the collimating function of the light collimator layer may be improved.

FIG. 1G″ illustrates some variations of the semiconductor device 10 of the present embodiment. It should be noted that, unless otherwise specified, elements of the embodiments of FIG. 1G″ that are the same as or similar to the elements of the above embodiments will be denoted by the same reference numerals, and the formation methods thereof may be the same as or similar to those of the above embodiments.

As shown in FIG. 1G″, one difference between the semiconductor device 10′ and the semiconductor device 10 is that the top surfaces of the transparent pillars of the semiconductor device 10′ are level with the top surface of the light-shielding layer. For example, in some embodiments, after the transparent pillars 106 are formed, a planarization process may be performed to planarize the transparent pillars 106, such that the top surfaces of the transparent pillars 106 may be substantially level with the top surface of the light-shielding layer 102. In other words, in these embodiments, the top surfaces of the transparent pillars 106 may be coplanar with the top surface of the light-shielding layer 102. Similarly, in some embodiments, after the transparent pillars 106′ are formed, a planarization process may be performed to planarize the transparent pillars 106′, such that the top surfaces of the transparent pillars 106′ may be substantially level with the top surface of the light-shielding layer 102′. In other words, in these embodiments, the top surfaces of the transparent pillars 106′ may be coplanar with the top surface of the light-shielding layer 102′. For example, the planarization process may include a grinding process, a chemical mechanical polishing process, an etch back process, any other applicable process, or a combination thereof.

### Embodiment 2

One difference between Embodiment 1 and Embodiment 2 is that the method for forming the semiconductor device of Embodiment 2 uses a stencil having only one opening to dispose the first material on the substrate.

It should be noted that, unless otherwise specified, the elements of Embodiment 2 the same as or similar to those of the above embodiments will be denoted by the same reference numerals, and the formation methods thereof may be the same as or similar to those of the above embodiments.

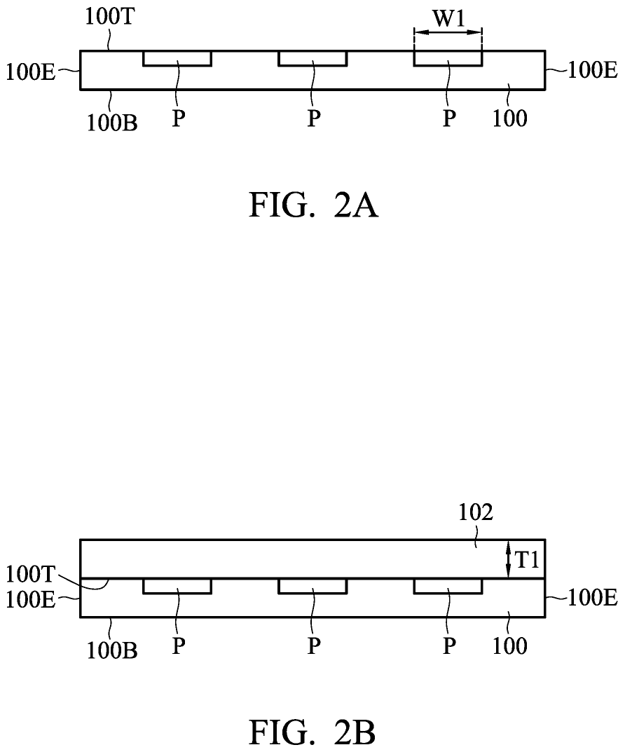

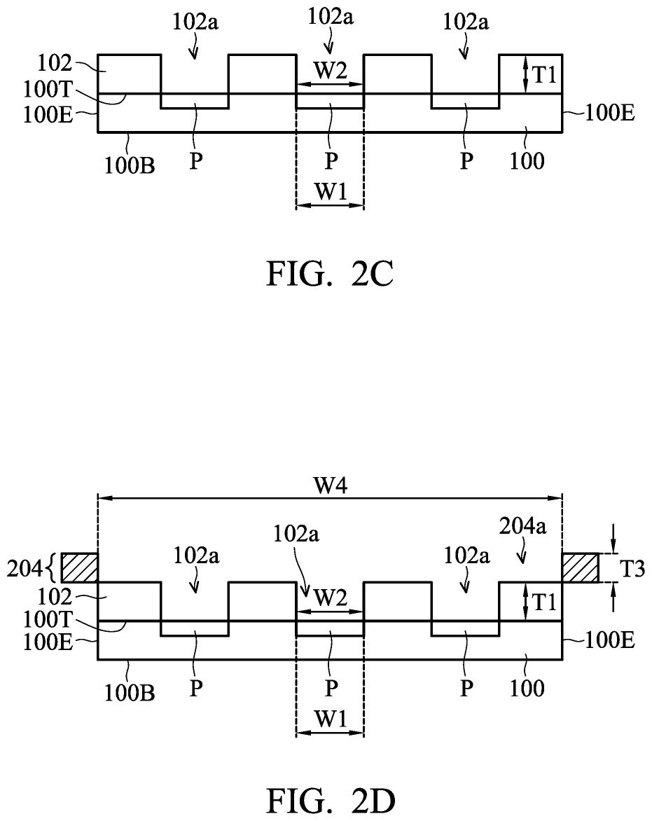

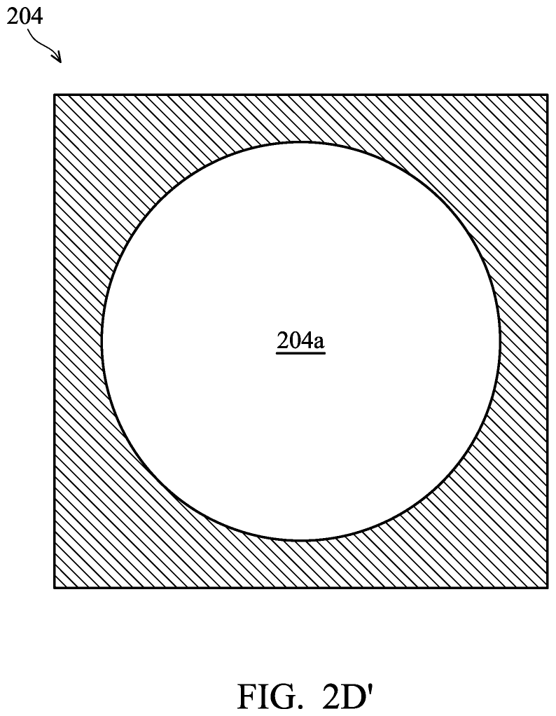

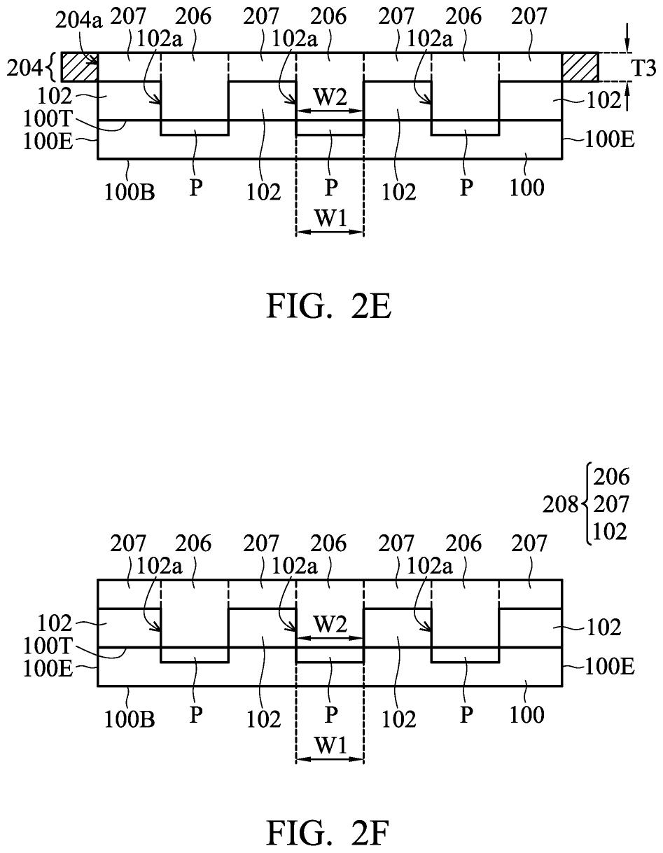

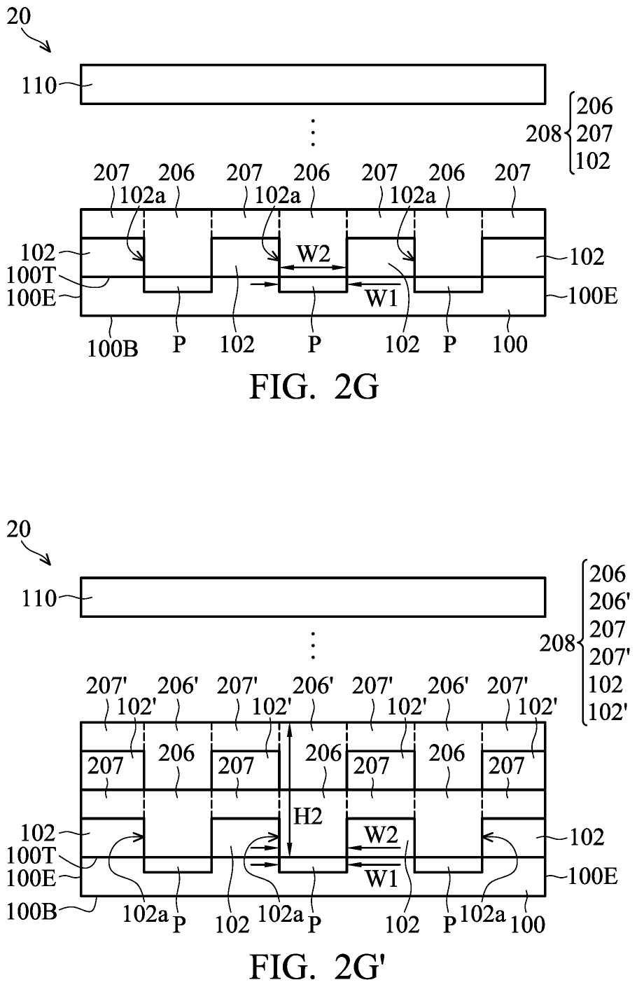

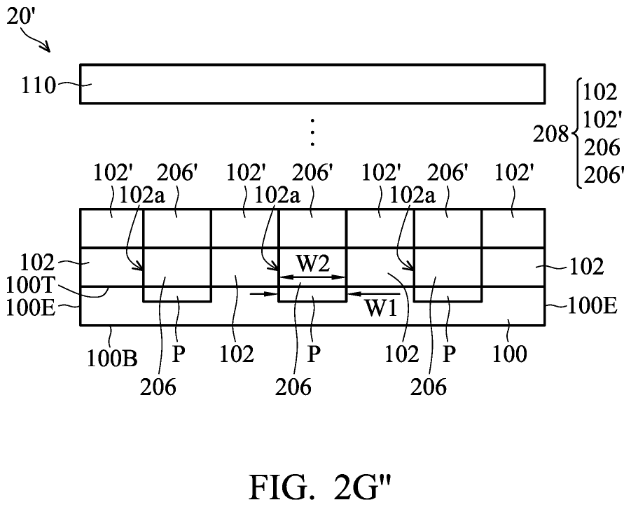

First, as shown in FIG. 2A, a substrate 100 is provided. Then, as shown in FIGS. 2B and 2C, a light-shielding layer 102 is formed on the substrate 100, and a plurality of openings 102a are formed in the substrate 100 to expose pixels P of the substrate 100. It should be understood that, the steps illustrated in FIGS. 2A to 2C are the same as or similar to the steps illustrated in FIGS. 1A to 1C. For simplicity and clarity, the details will not be repeated.

Then, as shown in FIG. 2D, a stencil 204 is placed on the top surface 100T of the substrate 100 and the light-shielding layer 102. In some embodiments, the stencil 204 may have only one opening (i.e., the opening 204a). In some embodiments, the opening 204a corresponds to a plurality of pixels P. In other words, in these embodiments, after the stencil 204 is placed on the top surface 100T of the substrate 100 and the light-shielding layer 102, the opening 204a may expose the plurality of pixels P which the opening 204a corresponds to. In some embodiments, as shown in FIG. 2D, after the stencil 204 is placed on the top surface 100T of the substrate 100 and the light-shielding layer 102, the opening 204a is connected to the plurality of openings 102a.

As shown in FIG. 2D, the stencil 204 may have a thickness T3, and the opening 204a may have a width W4. For example, the thickness T3 may be between 10 μm and 100 μm, but the present disclosure is not limited thereto. For example, the width W4 may be within a range of 50 cm to 550 cm, but the present disclosure is not limited thereto.

In some embodiments, as shown in FIG. 2D, the width W4 of the opening 204a may be greater than the width W1 of the pixel P. In some embodiments, as shown in FIG. 2D, the width W4 of the opening 204a may be greater than the width W2 of the opening 102a.

Then, referring to FIG. 2D′ which illustrates a top view of the stencil 204, in some embodiments shown in FIG. 2D′, the opening 204a of the stencil 204 forms an openwork pattern in the stencil 204. In subsequent steps, the first material discussed in Embodiment 1 may be disposed on the top surface 100T of the substrate 100 through the openwork pattern of the stencil 204, such that the first material on the top surface 100T of the substrate 100 may have a pattern corresponding to the openwork pattern of the stencil 204. The details will be discussed in the following paragraphs.

In some embodiments, as shown in FIG. 2D′, the opening 204a may be substantially round, but the present disclosure is not limited thereto. In some other embodiments, the opening 204a may be rectangular, oval, oblong, hexagonal, irregular-shaped, any other applicable shape, or a combination thereof according to design requirements.

For example, the stencil 204 may be made of steel, but the present disclosure is not limited thereto. For example, the opening 204a may be formed in the stencil 204 by a mechanical drilling process, but the present disclosure is not limited thereto.

Then, as show in FIG. 2E, a plurality of transparent pillars 206 and transparent connection features 207 are formed on the substrate 100. In some embodiments, as shown in FIG. 2E, the transparent pillars 206 are disposed in the openings 102a and extend into the opening 204a, and the transparent pillars 206 cover the pixels P of the substrate 100. In some embodiments, as shown in FIG. 2E, the transparent connection features 207 are disposed on the light-shielding layer 102 and connected to the transparent pillars 206. In other words, in these embodiments, the transparent pillars 206 may be connected to each other through the transparent connection features 207.

The transparent pillars 206 and the transparent connection features 207 may be made of the first material. In some embodiments, the first material may include a transparent material (e.g., transparent photoresist, polyimide, any other applicable material, or a combination thereof). In some embodiments, the first material may include a light curing material, a thermal curing material, or a combination thereof. In some embodiments, the flowability of the first material may be the same as or similar to gel or glue.

In some embodiments, the stencil 204 may be used to perform a stencil printing process to coat (or print) the first material onto the top surface 100T of the substrate 100. In some embodiments, in the stencil printing process, the first material is disposed on the stencil 204, and then a squeegee or a roller (not shown in the figures) may be moved on the top surface of the stencil 204 along a direction parallel to the top surface 100T of the substrate 100. The squeegee or the roller may provide an applicable pressure on the first material, such that the first material is squeezed into the opening 204a and the openings 102a from the top surface of the stencil 204. In some embodiments, since the first material is disposed on the top surface 100T of the substrate 100 through the openwork pattern of the stencil 204, the pattern of the transparent pillars 206 and the transparent connection features 207 may correspond to the openwork pattern of the stencil 204. In some embodiments, the pattern of the transparent pillars 206 and the transparent connection features 207 may be substantially the same as the openwork pattern of the stencil 204.

In some embodiments, since the light-shielding layer 102 and the openings 102a exposing the pixels P are formed before the first material is coated (or printed) on the top surface 100T of the substrate 100 by performing the stencil printing process with the stencil 204, the transparent pillars 206 made of the first material may be precisely disposed on the pixels P. Therefore, the collimating function of the light collimator layer (i.e., the light collimator layer 208 which will be discussed in the following paragraphs) may be improved.

Then, as shown in FIG. 2F, the stencil 204 is removed from the substrate 100 and the light-shielding layer 102. In some embodiments, a curing process may be performed to cure the first material of the transparent pillars 206 and the transparent connection features 207 after the stencil 204 is removed from the substrate 100 and the light-shielding layer 102. For example, the curing process may be a light curing process, a thermal curing process, or a combination thereof.

In some embodiments, as shown in FIG. 2F, the transparent pillars 206, the transparent connection features 207, and the light-shielding layer 102 may serve as a light collimator layer 208 of a semiconductor device. In some embodiments, the light-shielding layer 102 and the transparent pillars 206 of the light collimator layer 208 may be staggered with each other.

In some embodiments, the light-shielding layer 102 of the light collimator layer 208 is black (e.g., the light-shielding layer 102 is made of black photoresist, black ink, black molding compound, or black solder mask), and thus the collimating function of the light collimator layer 208 may be improved.

For example, in some embodiments, a light source (e.g., a light-emitting diode) (not shown in the figures), a blocking layer (not shown in the figures), any other applicable element, or a combination thereof may be disposed on the light collimator layer 208, and a cover plate 110 (e.g., a glass cover plate) may be disposed on these optical elements to form a semiconductor device 20 (as shown in FIG. 2G) such as a fingerprint identification device.

In some embodiments, the steps illustrated in FIGS. 2B to 2F may be repeated (e.g., repeated for twice, three times, or any other applicable number of times), such that the light collimator layer 208 of the semiconductor device 20 may include more light-shielding layers, transparent pillars, and transparent connection features, further improving the collimating function of the light collimator layer 208. For example, as shown in FIG. 2G′, in some embodiments, the steps illustrated in FIGS. 2B to 2F may be repeated to form a light-shielding layer 102′ the same as or similar to the light-shielding layer 102, transparent pillars 206′ the same as or similar to the transparent pillars 206, and transparent connection features 207′ the same as or similar to the transparent connection features 207 on the substrate 100. In some embodiments, the steps illustrated in FIGS. 2B to 2F may be repeated for any applicable number of times to increase the ratio of the sum of the heights of the transparent pillars on a pixel P to the width of the pixel P (e.g., H2/W1), so as to improve the collimating function of the light collimator layer 208. In some embodiments, the ratio of the sum of the heights of the transparent pillars on a pixel P to the width of the pixel P (e.g., H2/W1) may be between 2 and 30 (e.g., within a range of 10 to 30).

In some embodiments, as shown in FIG. 2G′, the top surfaces of the transparent pillars 206 are higher than the top surface of the light-shielding layer 102. In some embodiments, as shown in FIG. 2G′, the top surfaces of the transparent pillars 206′ are higher than the top surface of the light-shielding layer 102′.

In some embodiments, the transparent connection features 207 are disposed between the light-shielding layer 102′ and the light-shielding layer 102. In some embodiments, the light-shielding layer 102 and the light-shielding layer 102′ may be made of the same material, but the present disclosure is not limited thereto. In some other embodiments, the light-shielding layer 102 and the light-shielding layer 102′ may be made of different materials.

In some embodiments, the transparent pillars 206′ may be in direct contact with the transparent pillars 206. In some embodiments, the transparent pillars 206 and the transparent pillars 206′ may be made of the same material, but the present disclosure is not limited thereto. In some other embodiments, the transparent pillars 206 and the transparent pillars 206′ may be made of different materials.

In summary, in the method for forming the semiconductor device of the present embodiment, a light-shielding layer is formed on a substrate and a plurality of openings are formed in the light-shielding layer, and then a transparent material is disposed on the substrate to form a plurality of transparent pillars by a stencil printing process. The light-shielding layer and the transparent pillars may serve as the light collimator layer of the semiconductor device (e.g., a fingerprint identification device). Since the cost of the stencil printing process is low, the manufacturing cost of the light collimator layer and the semiconductor device including the light collimator layer may be reduced. In addition, in some embodiments, since the light-shielding layer and the openings which are in the light-shielding layer and expose the pixels of the substrate are formed before the transparent pillars are formed, the transparent pillars may be precisely disposed on the pixels of the substrate. Therefore, the collimating function of the light collimator layer may be improved.

FIG. 2G″ illustrates some variations of the semiconductor device 20 of the present embodiment. It should be noted that, unless otherwise specified, elements of the embodiments of FIG. 2G″ that are the same as or similar to the elements of the above embodiments will be denoted by the same reference numerals, and the formation methods thereof may be the same as or similar to those of the above embodiments.

As shown in FIG. 2G″, one difference between the semiconductor device 20′ and the semiconductor device 20 is that the top surfaces of the transparent pillars of the semiconductor device 20′ are level with the top surface of the light-shielding layer. For example, in some embodiments, after the transparent pillars 206 are formed, a planarization process may be performed to planarize the transparent pillars 206, such that the top surfaces of the transparent pillars 206 may be substantially level with the top surface of the light-shielding layer 102. In other words, in these embodiments, the top surfaces of the transparent pillars 206 may be coplanar with the top surface of the light-shielding layer 102. In some embodiments, the planarization process also removes the transparent connection features 207. Similarly, in some embodiments, after the transparent pillars 206′ are formed, a planarization process may be performed to planarize the transparent pillars 206′, such that the top surfaces of the transparent pillars 206′ may be substantially level with the top surface of the light-shielding layer 102′. In other words, in these embodiments, the top surfaces of the transparent pillars 206′ may be coplanar with the top surface of the light-shielding layer 102′. In some embodiments, the planarization process also removes the transparent connection features 207.

It should be understood that although the top surfaces of the transparent pillars 206 are substantially level with the top surface of the light-shielding layer 102, and the top surfaces of the transparent pillars 206′ are substantially level with the top surface of the light-shielding layer 102′ in the embodiments illustrated in FIG. 2G″, the present disclosure is not limited thereto. For example, in some embodiments, the top surfaces of the transparent pillars 206 are substantially level with the top surface of the light-shielding layer 102, the top surfaces of the transparent pillars 206′ are higher than the top surface of the light-shielding layer 102′, and the connection features 207′ are not removed. For example, in some embodiments, the top surfaces of the transparent pillars 206′ are substantially level with the top surface of the light-shielding layer 102′, the top surfaces of the transparent pillars 206 are higher than the top surface of the light-shielding layer 102, and the connection features 207 are not removed.

It should be understood that, in some embodiments, the transparent pillars of the light collimator layer may be formed by a plurality of stencils having different openwork patterns. For example, in some embodiments, the stencil 104 of Embodiment 1 may be used to form the transparent pillars 106 on the pixels P of the substrate 100, and then the stencil 204 of Embodiment 2 may be used to form the transparent pillars 206 on the transparent pillars 106.

In summary, in the method for forming the semiconductor device of the embodiments of the present disclosure, a light-shielding layer is formed on a substrate and a plurality of openings are formed in the light-shielding layer, and then a transparent material is disposed on the substrate to form a plurality of transparent pillars by a stencil printing process. The light-shielding layer and the transparent pillars may serve as the light collimator layer of the semiconductor device (e.g., a fingerprint identification device). Since the cost of the stencil printing process is low, the manufacturing cost of the light collimator layer and the semiconductor device including the light collimator layer may be reduced. In addition, in some embodiments, since the light-shielding layer and the openings which are in the light-shielding layer and expose the pixels of the substrate are formed before the transparent pillars are formed, the transparent pillars may be precisely disposed on the pixels of the substrate. Therefore, the collimating function of the light collimator layer may be improved.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Furthermore, each claim may be an individual embodiment of the present disclosure, and the scope of the present disclosure includes the combinations of every claim and every embodiment of the present disclosure.

1-9. (canceled)

10. A semiconductor device, comprising:
a substrate, wherein the substrate comprises a plurality of pixels; and
a light collimator layer disposed on the substrate, wherein the light collimator layer comprises:
a first light-shielding layer disposed on the substrate;
a plurality of first transparent pillars disposed on the substrate, wherein the first transparent pillars cover the pixels of the substrate;
a second light-shielding layer disposed on the first light-shielding layer; and
a plurality of second transparent pillars disposed on the first transparent pillars and covering the first transparent pillars.

11. The semiconductor device of claim 10, wherein the first light-shielding layer is in direct contact with the second light-shielding layer.

12. The semiconductor device of claim 10, further comprising:
a plurality of transparent connection features disposed between the first light-shielding layer and the second light-shielding layer, wherein the transparent connection features are connected to the first transparent pillars.

13. The semiconductor device of claim 10, further comprising:
a plurality of transparent connection features disposed on the second light-shielding layer, wherein the transparent connection features are connected to the second transparent pillars.

14. The semiconductor device of claim 10, wherein top surfaces of the second transparent pillars are higher than a top surface of the second light-shielding layer.

15. The semiconductor device of claim 10, wherein top surfaces of the first transparent pillars are higher than a top surface of the first light-shielding layer.

16. The semiconductor device of claim 10, wherein the first transparent pillars and the second transparent pillars are made of a light curing material, a thermal curing material, or a combination thereof.

17. The semiconductor device of claim 10, wherein the pixels of the substrate are arranged in an array.

18. The semiconductor device of claim 10, wherein each of the pixels of the substrate comprises at least one photodiode.
